(19) United States
(12) Patent Application Publication
(10) Pub. No.: US 2015/0179666 A1
(43) Pub. Date: Jun. 25, 2015

(54) WIRING STRUCTURE OF ARRAY SUBSTRATE

(71) Applicant: SHENZHEN CHINA STAR OPTOELECTRONICS TECHNOLOGY CO., LTD., Shenzhen, Guangdong (CN)

(72) Inventor: Li Chai, Shenzhen (CN)

(21) Appl. No.: 14/240,385

(22) PCT Filed: Jan. 23, 2014
(86) PCT No.: PCT/CN2014/071182

§ 371 Date: Jun. 13, 2014

(30) Foreign Application Priority Data
Dec. 25, 2013 (CN) 201310726450.4

(51) Int. Cl. H01L 27/12; G02F 1/1368; G02F 1/1362

(52) U.S. Cl. CPC H01L 27/124; G02F 1/136286; G02F 1/1368

(57) ABSTRACT

The present disclosure relates to the technical field of liquid crystal display. The wiring structure of the array substrate according to the present disclosure includes an RGB combined line serving as data lines in a curing process, an OE combined line serving as scan lines in the curing process, an array substrate common line, a color filter substrate common line, and corresponding RGB curing pad, OE curing pad, an array substrate curing pad and a color filter substrate curing pad which are connected to the RGB combined line, the OE combined line, the array substrate common line and the color filter substrate common line respectively and are configured to receive respective voltages. The present disclosure reduces the number of curing bus lines by improving the conventional design, which helps to reduce the peripheral wires of the array substrate, increase the buffer space for design layout and alleviate the risk of manufacturing defects. This leads to progress over prior art.

### FIELD OF THE INVENTION

The present disclosure relates to the technical field of liquid crystal display, and particularly, relates to a wiring structure of an array substrate.

### BACKGROUND OF THE INVENTION

With the development of information society, the demand for display equipment is continuously growing, thus rapid development is promoted in the liquid crystal panel industry. Accordingly, demands on quantity and quality of display panels are both rapidly increasing, with higher requirements on the design and processing capability.

Generally, a wiring structure is required for curing lines in designing the array substrate in a thin film transistor-liquid crystal display (TFT LCD) obtained through a polymer stabilize vertical align (PSVA) process. With this wiring structure, an array test pad, which is used for panel electric inspection of probes after the manufacturing process of the array substrate is completed, can be connected with a curing pad, which is used for curing the probes of the liquid crystal panel. Generally, array test bus lines and curing bus lines are equal in number, and are in one-to-one correspondence. In this case, peripheral wires should be increased in the design of the products due to the demand of curing wires, thus causing risks to the design layout and process yield.

Accordingly, in the prior art, a wiring structure for curing lines is provided in designing the TFT LCD array substrate obtained through the polymer stabilize vertical align (PSVA) process, for curing probes in the manufacturing process of the vertical align liquid crystal panel.

FIG. 1 shows a wiring structure of an array substrate in the prior art. With reference to FIG. 1, the wiring structure of the array substrate of the vertical align liquid crystal panel in the prior art includes a red line 14, a green line 15, a blue line 16, an odd line 17, an even line 18, an array substrate common line 13 and a color filter substrate common line 19, i.e. seven curing lines in total. Among others, the red line 14, the green line 15 and the blue line 16 function as data lines during the curing process, while the odd line 17 and the even line 18 function as scan lines during the curing process. In the prior art, the wiring structure of the vertical align liquid crystal panel further includes seven corresponding curing pads and an array substrate test pad. During the curing process, when a voltage is applied to a curing pad, the voltage is then applied to a corresponding capacitor through a corresponding wire, namely one of the above-mentioned seven lines, connected with said curing pad.

Thus, the wiring structure of the vertical align liquid crystal panel in the prior art includes at least seven wires to be cured.

Generally, in order to apply a curing voltage through the common line 13 of a thin film transistor array substrate, an additional curing pad 13-1 is required, which should be electrically connected to the common line 13 of each pixel in a pixel display area of the array substrate through a wire. Thus, the curing voltage may be applied to the curing pad 13-1, which is connected with the array substrate common line 13 through the wire. Finally, the voltage can be transmitted to the corresponding storage capacitor of each pixel in the pixel display area.

However, before the wire of the curing pad 13-1 is connected with the array substrate common line 13, it may span across, bridge over, or penetrate through some other wires. For example, the wire of the curing pad 13-1 as shown in FIG. 1 is connected with other wires to form a wiring area, which leads to a risk of electronic static discharge (ESD).

It could be seen that the seven wires would occupy a certain layout space of the array substrate. For a fixed glass substrate size, the more wires are required, the smaller space would be left. Furthermore, once there are more wires, more intersections would be generated, which leads to an increased risk of electronic static discharge (ESD) at the regions surrounding the intersections, and also leads to an increased risk of product yield loss.

Aiming at solving the above-mentioned defects in the prior art, the present disclosure improves the wiring structure of the array substrate.

### SUMMARY OF THE INVENTION

As mentioned above, in a wiring structure of an array substrate in the prior art, the seven wires would occupy the layout space of the array substrate. For a fixed glass substrate size, the more wires are required, the smaller space would be left. Furthermore, once there are more wires, more intersections would be generated, which leads to an increased risk of electronic static discharge (ESD) at the regions surrounding the intersections, and also leads to an increased risk of product yield loss.

According to the present disclosure, based on the practical signal input for curing probes in a vertical align liquid crystal panel, the curing wire design of the array substrate of the vertical align liquid crystal panel can be improved, and the number of the curing wires can be reduced, which helps to increase the space for design, alleviate the risk of yield loss, and reduce the number of necessary curing pads. In the meantime, the number of necessary curing probes for the liquid crystal panel can be reduced, thus lowering the cost of large-scale production.

Therefore, the present disclosure provides a wiring structure of an array substrate.

The wiring structure of the array substrate according to the present disclosure includes an RGB combined line serving as data lines in a curing process, an OE combined line serving as scan lines in the curing process, an array substrate common line, a color filter substrate common line, and an RGB curing pad, an OE curing pad, an array substrate curing pad and a color filter substrate curing pad which are connected to the RGB combined line, the OE combined line, the array substrate common line and the color filter substrate common line respectively and are configured to receive respective voltages.

In such a manner, compared with the prior art, the wiring structure according to the present disclosure can reduce the number of wires and curing pads, which helps to reduce peripheral wires of the array substrate, increase a buffer space for design layout and reduce the risk of manufacturing defects. With the number of curing wires reduced, the design space is increased, the yield loss risk is decreased, the number of the curing pads is reduced, and meanwhile, the required number for curing probes of the liquid crystal panel is also reduced, which greatly lowers the cost of large-scale production.

Preferably, the RGB combined line includes a red line, a blue line and a green line, two adjacent lines of the red line, and the blue line and the green line are connected with each other through a first thin-film transistor, which can be controlled to be in on or off state through the gate of the first thin-film transistor, so that the two adjacent lines can be controlled to be short-circuited or disconnected. The adjacent lines are connected through the thin-film transistor, so that the red line, the blue line and the green line can be conveniently, quickly and uniformly controlled, with the result of reduced energy consumption and improved efficiency of curing process.

Preferably, the wiring structure further includes a first signal line capable of applying a signal voltage, and the gate of the first thin-film transistor is connected to the first signal line. The first signal line is configured to control the first thin-film transistor.

Preferably, the red line and the blue line are connected with each other through the first thin-film transistor, and the green line and the blue line are connected with each other through the first thin-film transistor.

Preferably, the blue line and the red line are connected with each other through the first thin-film transistor, and the green line and the red line are connected with each other through the first thin-film transistor.

Preferably, the blue line and the green line are connected with each other through the first thin-film transistor, and the red line and the green line are connected with each other through the first thin-film transistor.

Preferably, the OE combined line includes an odd line and an even line connected with each other through a second thin-film transistor, and the second thin-film transistor is controlled to be in on or off state through the gate of the second thin-film transistor, so that the odd line and the even line can be controlled to be short-circuited or disconnected. The odd line and the even line are connected through the thin-film transistor, so that the odd line and the even line can be conveniently, quicicly and uniformly controlled, with the result of reduced energy consumption and improved efficiency of curing process.

Preferably, the wiring structure further includes a second signal line capable of applying a signal voltage, and the gate of the second thin-film transistor is connected to the second signal line. The second signal line is configured to control the second thin-film transistor.

Preferably, the wiring structure further includes at least one auxiliary curing line and an auxiliary curing pad connected to the auxiliary curing line.

Preferably, the auxiliary curing line is connected to the gates of the first thin-film transistor and the second thin-film transistor, and the auxiliary curing pad is configured to receive the gate voltages of the first thin-film transistor and the second thin-film transistor. Through only one auxiliary curing line, the red line, the green line, the blue line, the odd line and the even line can be conveniently, quickly and uniformly controlled on and off, with the result of reduced energy consumption and improved efficiency of curing process.

Meanwhile, the present disclosure reduces the number of curing bus lines by improving the conventional design, which helps to reduce the peripheral wires of the array substrate, increase the buffer space for design layout and alleviate the risk of manufacturing defects. On the other hand, intersections of circuits are reduced, and the risk of electronic static discharge (ESD) at the intersections can be effectively prevented.

The above-mentioned technical features may be combined in various appropriate manners or substituted by equivalent technical features, as long as the objective of the present disclosure can be fulfilled.

### BRIEF DESCRIPTION OF THE DRAWINGS

The present disclosure will be described in more detail below based on nonfinite examples with reference to the accompanying drawings. In the drawings:

FIG. 1 shows a wiring structure of an array substrate in the prior art;

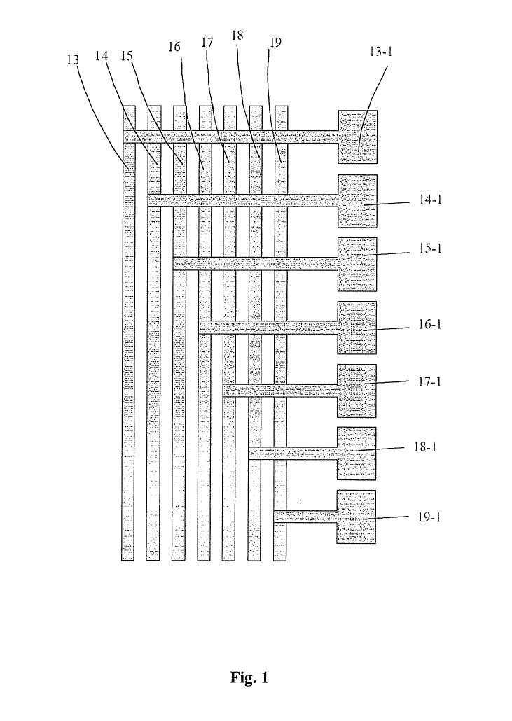

FIG. 2 shows arrangement of a red line, a green line, a blue line, an odd line and an even line of the wiring structure of the array substrate in the prior art;

FIG. 3 shows a wiring structure of an array substrate according to the present disclosure; and

FIG. 4 shows arrangement of an RGB combined line and an OE combined line of the wiring structure of the array substrate according to the present disclosure.

In the drawings, the same components are indicated by the same reference signs. The accompanying drawings are not drawn in an actual scale.

### DETAILED DESCRIPTION OF THE EMBODIMENTS

The present disclosure will be introduced in detail below with reference to the accompanying drawings.

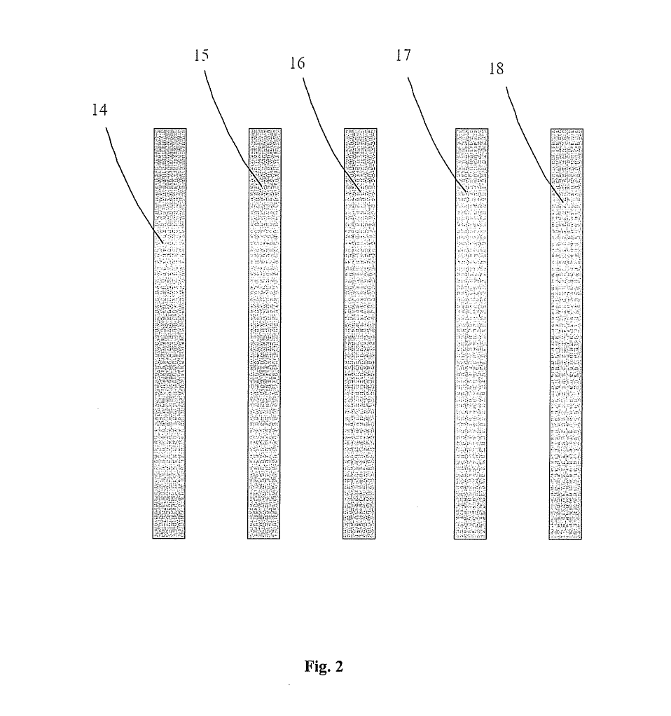

FIG. 2 shows arrangement of a red line 14, a green line 15, a blue line 16, an odd line 17 and an even line 18 of a wiring structure of a vertical align liquid crystal panel in the prior art. It could be seen that in the prior art, the red line 14, the green line 15, the blue line 16, the odd line 17 and the even line 18 receive respective voltages separately as five mutually independent lines.

With reference to FIG. 2, through research, the applicant considers that the red line 14, the green line 15 and the blue line 16 are allowed to receive voltages of the same value at the same moment in the curing process. Similarly, the odd line 17 and the even line 18 are allowed to receive voltages of the same value at the same moment.

Accordingly, in the curing process, it is unnecessary for the red line 14, the green line 15 and the blue line 16 to receive the voltages separately as three mutually independent wires, and similarly, it is unnecessary either for the odd line 17 and the even line 18 to receive the voltages separately as two mutually independent wires.

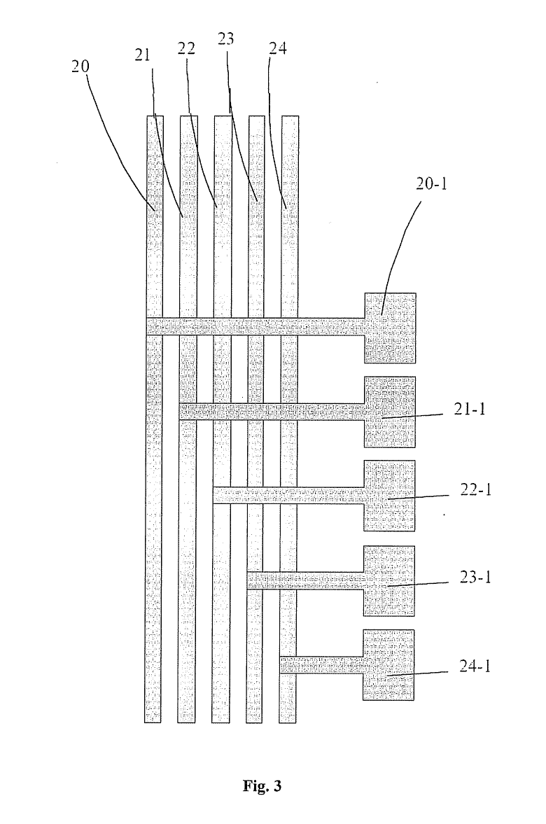

Thus, the present disclosure proposes a wiring structure of an array substrate. FIG. 3 shows the wiring structure of an array substrate of a vertical align liquid crystal panel according to the present disclosure.

With reference to FIG. 3, the wiring structure of the array substrate according to the present disclosure includes an RGB (red, green and blue) combined line 21 serving as data lines in a curing process, an OE (odd and even) combined line 22 serving as scan lines in the curing process, an array substrate common line 20, a color filter substrate common line 23, and an RGB (red, green and blue) curing pad 21-1, an OE (odd and even) curing pad 22-1, an array substrate curing pad 20-1 and a color filter substrate curing pad 23-1 which are connected to the RGB combined line 21, the OE combined line 22, the array substrate common line 20 and the color filter substrate common line 23 respectively, and are configured to receive respective voltages.

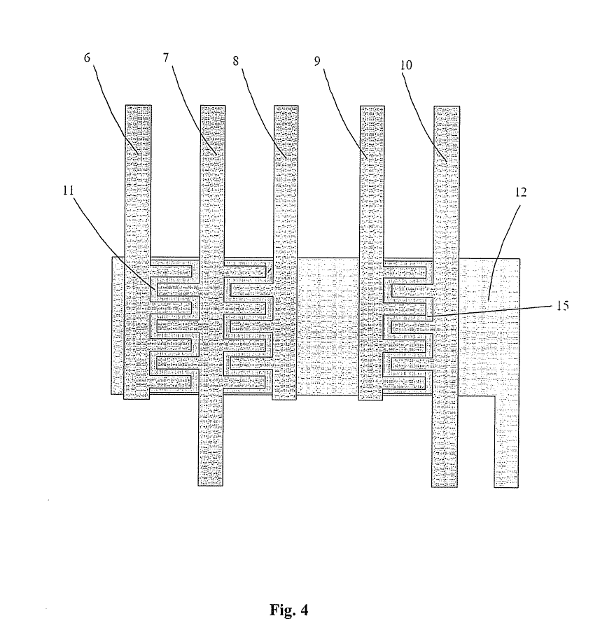

FIG. 4 shows arrangement of the RGB combined line and the OE combined line of the wiring structure of the array substrate according to the present disclosure.

With reference to FIG. 4, the RGB combined line 21 includes a red line 6, a blue line 8 and a green line 7, wherein two adjacent lines of the red line 6, the blue line 8 and the green line 7 are connected through a first thin-film transistor 11. The first thin-film transistor 11 can be controlled to be in on or off state through the gate of the first thin-film transistor 11, so that the two lines connected through the first thin-film transistor 11 can be controlled to be short-circuited or disconnected. The number of the first thin-film transistors 11 may be one or more according to the specific requirement on structural design.

In an example shown in FIG. 4, the blue line 8 and the green line 7 are connected with each other through the first thin-film transistor 11, and the green line 7 and the red line 6 are connected with each other through the first thin-film transistor.

Alternatively, it can also be configured such that the red line 6 and the blue line 8 are connected with each other through the first thin-film transistor 11, and the green line 7 and the blue line 8 are connected with each other through the first thin-film transistor 11.

Alternatively, it can also be configured such that the blue line 8 and the red line 6 are connected with each other through the first thin-film transistor 11, and the green line 7 and the red line 6 are connected with each other through the first thin-film transistor 11.

In an example, the wiring structure of the array substrate according to the present disclosure further includes a first signal line capable of applying a signal voltage, and the gate 12 of the first thin-film transistor 11 is connected to the first signal line.

With reference to FIG. 4, in a preferred example, the OE combined line 22 includes an odd line 9 and an even line 10 connected through a second thin-film transistor 15, and the second thin-film transistor 15 is controlled on and off through the gate of the second thin-film transistor 15, so that the odd line 9 and the even line 10 are controlled to be short-circuited or disconnected. The number of the first thin-film transistors 11 may be one or more according to the specific requirement on structural design.

In an example, the wiring structure further includes a second signal line capable of applying a signal voltage, and the gate 12 of the second thin-film transistor 15 is connected to the second signal line.

With reference to FIG. 3 again, the wiring structure of the array substrate according to the present disclosure further includes at least one auxiliary curing line 24 and an auxiliary curing pad 24-1 connected to the auxiliary curing line 24.

Preferably, the auxiliary curing line 24 is connected to the gates of the first thin-film transistor 11 and the second thin-film transistor 15, and the auxiliary curing pad 24-1 is configured to receive the gate voltages for the first thin-film transistor 11 and the second thin-film transistor 15.

Through modifying the wiring structure in the prior art, the present disclosure can achieve a reduced number of curing bus lines, which helps to reduce peripheral wires of the array substrate, increase a buffer space for layout, and reduce the risk of manufacturing defects. Compared with the prior art, a significant progress is achieved.

Although the present disclosure has been described with reference to the preferred examples, various modifications could be made to the present disclosure without departing from the scope of the present disclosure and components in the present disclosure could be substituted by equivalents. The present disclosure is not limited to the specific examples disclosed in the description, but includes all technical solutions falling into the scope of the claims.

1. A wiring structure of an array substrate, wherein the wiring structure includes an RGB combined line serving as data lines in a curing process, an OE combined line serving as scan lines in the curing process, an array substrate common line, a color filter substrate common line, and an RGB curing pad, an OE curing pad, an array substrate curing pad and a color filter substrate curing pad which are connected to the RGB combined line, the OE combined line, the array substrate common line and the color filter substrate common line respectively and are configured to receive respective voltages.

2. The wiring structure according to claim 1, wherein the RGB combined line includes a red line, a blue line and a green line, and
two adjacent lines of the red line, the blue line and the green line are connected with each other through a first thin-film transistor, which can be controlled to be in on or off state through the gate of the first thin-film transistor, so that the two adjacent lines can be controlled to be short-circuited or disconnected.

3. The wiring structure according to claim 2, wherein the wiring structure further includes a first signal line capable of applying a signal voltage, and the gate of the first thin-film transistor is connected to the first signal line.

4. The wiring structure according to claim 2, wherein the red line and the blue line are connected with each other through the first thin-film transistor, and the green line and the blue line are connected with each other through the first thin-film transistor.

5. The wiring structure according to claim 2, wherein the blue line and the red line are connected with each other through the first thin-film transistor, and the green line and the red line are connected with each other through the first thin-film transistor.

6. The wiring structure according to claim 2, wherein the blue line and the green line are connected with each other through the first thin-film transistor, and the red line and the green line are connected with each other through the first thin-film transistor.

7. The wiring structure according to claim 2, wherein the OE combined line includes an odd line and an even line connected with each other through a second thin-film transistor, and
the second thin-film transistor can be controlled to be in on or off state through the gate of the second thin-film transistor, so that the odd line and the even line can be controlled to be short-circuited or disconnected.

8. The wiring structure according to claim 7, wherein the wiring structure further includes a second signal line capable of applying a signal voltage, and the gate of the second thin-film transistor is connected to the second signal line.

9. The wiring structure according to claim 7, wherein the wiring structure further includes at least one auxiliary curing line and an auxiliary curing pad connected to the auxiliary curing line.

10. The wiring structure according to claim 9, wherein the auxiliary curing line is connected to the gates of the first thin-film transistor and the second thin-film transistor, and the auxiliary curing pad is configured to receive the gate voltages of the first thin-film transistor and the second thin-film transistor.
